(19) United States
(12) Patent Application Publication
(10) Pub. No.: US 2019/0285669 A1
(43) Pub. Date: Sep. 19, 2019

(54) MANAGEMENT DEVICE AND POWER SUPPLY SYSTEM

(71) Applicant: SANYO Electric Co., Ltd., Daito-shi, Osaka (JP)

(72) Inventor: Kimihiko Furukawa, Hyogo (JP)

(73) Assignee: SANYO Electric Co., Ltd., Daito-shi, Osaka (JP)

(21) Appl. No.: 16/301,664

(22) PCT Filed: May 9, 2017
(86) PCT No.: PCT/JP2017/017448

§ 371 Date: Nov. 14, 2018

(30) Foreign Application Priority Data
May 31, 2016 (JP) 2016-109387

(51) Int. Cl. G01R 19/165; G01R 31/382; H02J 7/00; H01M 10/48; H01M 10/42

(52) U.S. Cl. CPC G01R 19/165; G01R 31/382; H02J 7/0014; H01M 2010/4271; H01M 10/482; H01M 10/425; H02J 7/0026

(57) ABSTRACT

A cell voltage detection circuit is connected to each node of a plurality of cells connected in series by voltage detection lines, and detects the voltage of each of the cells. A total voltage detection circuit detects the voltage between the highest node and the lowest node of the cells. When the cell voltage of the highest cell or the lowest cell detected by the cell voltage detection circuit is abnormal, a controlling circuit compares the voltage detected by the total voltage detection circuit and a cell voltage sum obtained by adding the cell voltages of the cells detected by the cell voltage detection circuit. When the two voltages match, it is determined that the highest or the lowest cell is abnormal, and when the two voltages do not match, it is determined that a disconnection of the highest or the lowest voltage detection line has occurred.

### TECHNICAL FIELD

The present invention relates to a management device and a power supply system that manage a state of power storage modules.

### BACKGROUND ART

In recent years, hybrid vehicles (HV), plug-in hybrid vehicles (PHV), and electric vehicles (EV) are being spread. Secondary batteries as a key device are installed in these vehicles. As secondary batteries for the vehicle, the nickel hydride batteries and the lithium ion batteries are spread. In the future, it is expected that spread of the lithium ion batteries having high energy density are accelerated.

Since the operable voltage range and the prohibited voltage range in the lithium ion batteries are close, the stricter voltage management is necessary in the lithium ion batteries than other types of batteries. When an assembled battery in which a plurality of the lithium ion battery cells are connected in series is used, a voltage detection circuit is provided for detecting each of the battery cells. Each node of the plurality of cells and the voltage detection circuit are connected by a plurality of voltage detection lines (for example, refer to Patent Literatures 1). The detected voltages are used for a state-of-charge (SOC) management, an equalization control, and the like.

When a terminal voltage of the voltage detection circuit connected to this disconnected voltage detection line is decreased due to the disconnection of the voltage detection line, it cannot be immediately determined if the voltage detection line of the voltage detection circuit is disconnected, or if the cell voltage decreases. Then, there is a way to confirm if the disconnection occurs or if the cell voltage decreases, by making an equalizing circuit disposed between this voltage detection line and the voltage detection line by one lower than this conductive. When the corresponding cell voltage is about zero and the cell voltage by one higher than this cell is about the two-times value of the normal voltage value, the disconnection of the voltage detection line can be determined. On the other hand, when the corresponding cell voltage is about zero and the cell voltage by one higher than this cell is the normal voltage value, the decrease of the corresponding cell voltage can be determined.

### CITATION LIST

### Patent Literature

Patent Literature 1: Unexamined Japanese Patent Publication No. 2013-172544

### SUMMARY OF THE INVENTION

### Technical Problems

However, in the above-mentioned method, when the terminal voltage connected to the highest or the lowest voltage detection line has decreased, it is difficult to determine whether a voltage detection line is disconnected or the cell voltage has decreased.

The present disclosure is developed for solving such requirements. It is an object of the present disclosure to provide the following technology. In a voltage detection circuit which is connected, by voltage detection lines, to each node in a plurality of cells connected in series, the technology determines in a simple manner whether a voltage detection line is disconnected or the cell voltage has decreased when the terminal voltage connected to the highest or the lowest voltage detection line has decreased.

### Solution to Problem

To solve the above-mentioned requirements, a management device of one aspect of the present invention, includes:

a cell voltage detection circuit that is connected to each node of a plurality of cells connected in series by voltage detection lines, and detects the voltage of each of the cells; a total voltage detection circuit that detects the voltage between the highest node and the lowest node of the cells; and

a controlling circuit that compares the total voltage detected by the total voltage detection circuit and a cell voltage sum obtained by adding the cell voltages of the cells detected by the cell voltage detection circuit when the cell voltage of the highest cell or the lowest cell detected by the cell voltage detection circuit is abnormal.

In a case where the total voltage and the cell voltage sum match, the controlling circuit determines that the highest cell or the lowest cell is abnormal, and

in a case where the total voltage and the cell voltage sum do not match, the controlling circuit determines that a disconnection of the highest voltage detection line or the lowest voltage detection line occurs.

Any desired combinations of the above-described components and converted expressions of the present invention in methods, devices, systems, and other similar entities are still effective as aspects of the present invention.

### Advantageous Effect of Invention

According to the one aspect of the present invention, in a voltage detection circuit which is connected, by voltage detection lines, to each node in a plurality of cells connected in series, it is simply determined whether a voltage detection line is disconnected or the cell voltage has decreased when the terminal voltage connected to the highest or the lowest voltage detection line decreases.

### BRIEF DESCRIPTION OF DRAWINGS

FIG. 1 is a diagram for describing a power supply system according to an exemplary embodiment 1 of the present invention.

FIG. 2 is a flowchart illustrating a method of a disconnection detection in a highest or lowest voltage detection line, by a management device according to the exemplary embodiment 1.

FIG. 3 is a diagram for describing a power supply system according to an exemplary embodiment 2 of the present invention.

### DESCRIPTION OF EMBODIMENTS

### First Exemplary Embodiment

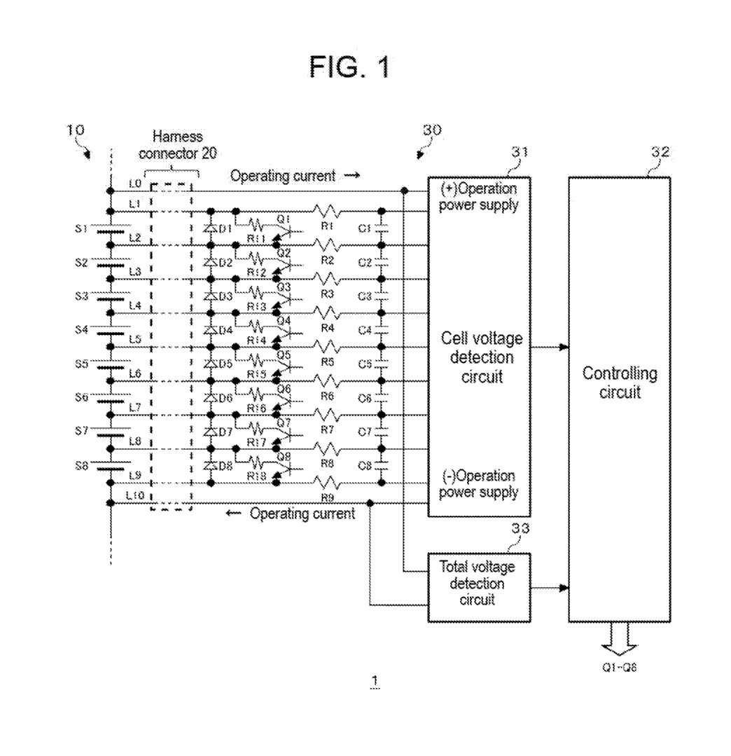

FIG. 1 is a diagram for describing a power supply system according to an exemplary embodiment 1. Power supply system 1 includes power storage module 10 and management device 30. Power storage module 10 includes a plurality of cells connected in series. A lithium ion battery cell, a nickel hydride battery cell, a lead battery, an electric double layer capacitor cell, a lithium ion capacitor cell, or the like can be used for the cells. Hereinafter, in the description, an example is supposed that uses a lithium ion battery cell (nominal voltage: 3.6 V to 3.7 V). FIG. 1 shows an example using the assembled battery in which 8 pieces of the lithium ion battery cells (first cell S1-eighth cell S8) are connected in series.

Management device 30 includes an equalizing circuit, an input filter, cell voltage detection circuit 31, controlling circuit 32, and total voltage detection circuit 33. Then, those are installed on a printed wiring board. Cell voltage detection circuit 31 is connected, by voltage detection lines L1-L9, to each node in a plurality of cells S1-S8 connected in series, a cell voltage detection circuit 31 is connected to each node of a plurality of cells S1-S8 connected in series by voltage detection lines L1-L9, and detects a voltage of each of cells S1-S8 by detecting voltages between adjacent voltage detection lines. Cell voltage detection circuit 31, for example, is configured of an ASIC (Application Specific Integrated Circuit) as the specific custom IC, or the like. Cell voltage detection circuit 31 transmits the detected voltage of each of cells S1-S8 to controlling circuit 32.

Each of wire harnesses is connected to each of the nodes of the plurality of cells S1-S8 of power storage module 10. Then, a tip connector of each of the wire harnesses is connected to each of connectors of management device 30 which is installed on the printed wiring board. Namely, power storage module 10 and management device 30 are electrically connected by harness connector 20.

Resistors R1-R9 are respectively inserted in voltage detection lines L1-L9, and capacitors C1-C8 are respectively connected between the adjacent two lines of the voltage detection lines. Resistors R1-R9 and capacitors C1-C8 constitute the input filter (low pass filter), and has a function in which the voltages inputted in cell voltage detection circuit 31 are stabilized.

Between the adjacent two lines of the voltage detection lines, diodes D1-D8 for a protection are respectively connected in reverse parallel to the plurality of cells S1-S8. For example, Zener diodes can be used for diodes D1-D8. Here, in a case where withstand voltage between the adjacent input terminals of cell voltage detection circuit 31 is designed at a voltage value higher than the voltage of the two cells, diodes D1-D8 can be omitted.

Each connector of management device 30 and each of the input terminals of cell voltage detection circuit 31 are connected by voltage detection lines L1-L9. The equalizing circuits are connected in parallel to the plurality of the cells S1-S8, respectively between the adjacent two lines of the voltage detection lines. In the example shown in FIG. 1, the equalizing circuit is configured of a series circuit of discharge resistors R11-R18 and discharge switches Q1-Q8. Discharge switches Q1-Q8, for example, are configured of transistors.

Controlling circuit 32 carries out equalizing controls based on the voltages received from cell voltage detection circuit 31. Concretely, controlling circuit 32 adjusts the voltages of the other cells except the cell of the lowest voltage, to the voltage of the cell of the lowest voltage among the plurality of cells S1-S8. Controlling circuit 32 turns on the discharge switches of the equalizing circuits which are connected in parallel to the other cells, and makes the other cells discharge. When the voltages of the other cells decrease to the voltage of the cell of the lowest voltage, controlling circuit 32 turns off the discharge switches of the equalizing circuits which are connected in parallel to the other cells. Controlling circuit 32, for example, is configured of a microprocessor.

The operation power supply of cell voltage detection circuit 31 is fed from power storage module 10 as the monitoring object, in order to simplify its power source circuit. In a case where the operation power supply of cell voltage detection circuit 31 is fed from a power source other than power storage module 10, a size of a circuit is increased due to an insulation treatment, to increase cost.

Generally, the circuit operating current of cell voltage detecting circuit 31 is approximately several mA to several tens mA. In a case where the power supply line also serves as a voltage detection line, a voltage drop caused by this circuit operating current, affects the detected voltage. Especially, in power supply system 1 in which lithium ion batteries are used that needs a high accurate management, this voltage drop cannot be ignored. Therefore, it is thought that the voltage detection line is separately wired from the power supply line.

In the example shown in FIG. 1, the highest node of the plurality of cells S1 to S8 constituting power storage module 10 and cell voltage detection circuit 31 are connected by two wires of first voltage detection line L1 and positive power supply line L0. Similarly, the lowest node of the plurality of cells S1 to S8 and cell voltage detection circuit 31 are connected by two wires of ninth voltage detection line L9 and negative power supply line L10.

Total voltage detection circuit 33 detects the voltage between positive power supply line L0 and negative power supply line L10, and detects the both-end voltage (hereinafter, described as the total voltage) of the plurality of cells S1-S8. Total voltage detection circuit 33 outputs the detected total voltage to controlling circuit 32. For example, total voltage detection circuit 33 can be configured of a combination of a resistance voltage-dividing circuit and an AD converter. Here, in a case where controlling circuit 32 incorporates an analog input terminal, total voltage detection circuit 33 can be configured of only a resistance voltage-dividing circuit.

Hereinafter, both of a connection failure and a disconnection are comprehensively called as “disconnection”. Namely, “disconnection” includes not only physically cutting wiring, but also electrically cutting. When the disconnection occurs at harness connector 20, it is impossible to properly detect a cell voltage by cell voltage detection circuit 31. In this case, a monitor of cell state or an equalization control by controlling circuit 32 cannot be properly carried out.

In order to detect the disconnection of harness connector 20, a way using the equalizing circuit is often used as explained below. Concretely, the equalizing circuit is disposed between a voltage detection line which is linked to the disconnected harness connector 20 and the voltage detection line by one lower than this line. When the equalizing circuit is made conductive, the cell voltage of a target for detection becomes about zero.

For example, in a case where the disconnection at harness connector 20 of seventh voltage detection line L7 of FIG. 1 occurs, when discharge switch Q7 is turned off, a voltage of seventh cell S7 detected by cell voltage detection circuit 31 becomes about zero, and a voltage of sixth cell S6 becomes about the two-times voltage of the one cell voltage. On the other hand, in a case where the voltage of seventh cell S7 decreases, when discharge switch Q7 is turned off, a voltage of seventh cell S7 detected by cell voltage detection circuit 31 is kept as the decreased voltage of seventh cell S7, and a voltage of sixth cell S6 is kept as the one cell voltage of sixth cell S6.

Thus, by making the equalizing circuit disposed between seventh voltage detection line L7 and eighth voltage detection line L8 conductive, whether seventh voltage detection line L7 is disconnected or the cell voltage of seventh cell S7 decreases, can be dearly detected. Then, a location where the failure or trouble occurs can be specified, based on the location of the equalizing circuit made conductive.

Even by the above-mentioned way, it is difficult to detect the disconnection of the highest voltage detection line L1 or the voltage decrease of the highest cell S1. That's the reason why there is no cell between positive power supply line L0 and voltage detection line L1. Similarly, it is also difficult to detect the disconnection of the lowest voltage detection line L9 or the voltage decrease of the lowest cell S9.

This exemplary embodiment compares the total voltage detected by total voltage detection circuit 33 and the sum (hereinafter, described as the cell voltage sum) obtained by adding the cell voltages of all cells S1-S8 detected by cell voltage detection circuit 31. Thereby, when the detected voltage of the highest or lowest cell decreases less than the predetermined value, it is possible to distinguish between the disconnection of harness connector 20 and the decrease of the cell voltage. Concretely, when the cell voltage sum is substantially equal to the total voltage, it is determined that the disconnection does not occur, namely, the voltage of the highest or lowest cell decreases actually. On the other hand, when the cell voltage sum is not substantially equal to the total voltage, it is determined that the highest or lowest voltage detection line is disconnected.

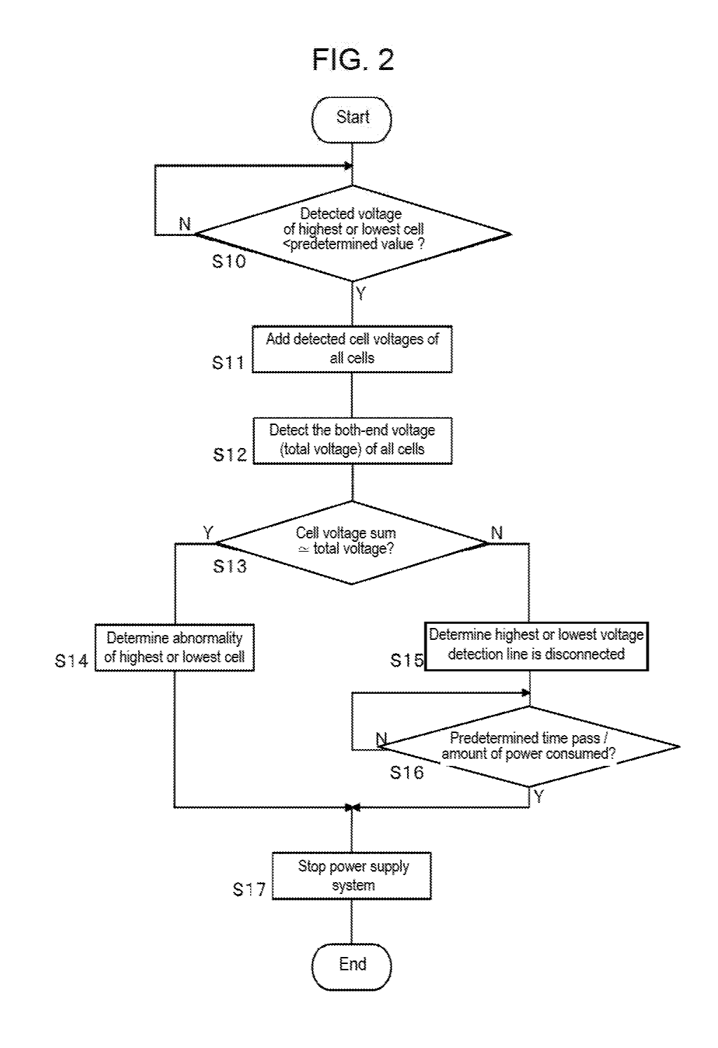

FIG. 2 is a flowchart illustrating a method of a disconnection detection in the highest or lowest voltage detection line, by management device 30 according to the exemplary embodiment 1. Cell voltage detection circuit 31 determines whether or not the detected voltage of the highest or lowest cell becomes less than the predetermined value (S10). For example, the predetermined voltage is set at the discharge end voltage of the cell, the voltage for determining the over-discharge of the cell, or the voltage obtained by adding a fixed margin to each of these voltages.

When the detected voltage of the highest or lowest cell becomes less than the predetermined value (Y of S10), controlling circuit 32 adds the cell voltages of all cells S1-S8 detected by cell voltage detection circuit 31 (S11). Total voltage detection circuit 33 detects the both-end voltage (the total voltage) of all cells S1-S8, and outputs it to controlling circuit 32 (S12). Here, in a state where the detected voltage of the highest or lowest cell is higher than the predetermined value, the detection of the total voltage by total voltage detection circuit 33 is not essential.

Controlling circuit 32 compares the added cell voltage sum and the total voltage detected by total voltage detection circuit 33 (S13). When the cell voltage sum is substantially equal to the total voltage (Y of S13), controlling circuit 32 determines that the highest or lowest cell is abnormal (over-discharge) (S14). Immediately or a predetermined short time after this determination, controlling circuit 32 stops power supply system 1 (S17). In a case of the use on vehicles, controlling circuit 32 notifies the higher rank ECU of a signal of stopping power, and the ECU displays a massage of showing a battery stop on the instrument panel. For example, usage states of the battery are shown by colors of the lamp, and the ECU changes colors of the lamp to a specific color showing the battery unusable. Alternatively, the ECU may output a voice massage showing the battery stop.

In a case where the vehicle is a hybrid car, simultaneously with outputting this message, the ECU changes the motor driving mode to the engine driving mode. In a case where the vehicle is a pure electric vehicle (EV), subsequently to that the ECU notifies the driver of this massage, after a necessary time (for example, several tens of seconds) passes for the driver's moving the vehicle to the road shoulder, controlling circuit 32 of power supply system 1 stops power supply system 1, and stops power supply to the motor.

In the above-mentioned step S13, when the cell voltage sum is not substantially equal to the total voltage (N of S13), controlling circuit 32 determines that the highest or lowest voltage detection line is disconnected (S15). Subsequently to this determination, until a predetermined time passes or a predetermined amount of electric power is consumed (N of S16), controlling circuit 32 allows power supply from power supply system 1 to the load including the motor. After the predetermined time passes or the predetermined amount of electric power is consumed (Y of S16), controlling circuit 32 stops power supply system 1 (S17). Subsequently to this determination, controlling circuit 32 notifies the higher rank ECU of a signal of a battery abnormality, and the ECU displays a massage of showing a battery abnormality on the instrument panel. For example, the usage states of the battery are shown by colors of the lamp, and the ECU changes colors of the lamp to a specific color showing the battery abnormality. Alternatively, the ECU may output a voice massage showing the battery abnormality.

In a case where the vehicle is a hybrid car, simultaneously with outputting this message, the ECU changes the motor driving mode to the engine driving mode. In a case where the vehicle is a pure electric vehicle (EV), subsequently to that the ECU notifies the driver of this massage, power supply to the motor is allowed, in order that the driver drives the vehicle to a location (for example, a gas station, a car dealer, or a repair shop) where a repair of the vehicle can be carried out.

This allowance of the power supply can be managed based on the time and/or the amount of electric power (approximately equal to travel distance). For example, the allowance time can be set at several to several tens minutes. Alternatively, the allowance travel distance can be set at several to several tens kilometers. Further, both of the allowance time and allowance travel distance can be used. During the allowance, by monitoring the total voltage detected by total voltage detection circuit 33, controlling circuit 32 monitors whether or not the over-charge/over-discharge of the whole of the cells occurs. Here, in the cells which are not affected by the disconnection of the voltage detection line, cell voltage detection circuit 31 continuously monitors such cells.

As explained above, according to this exemplary embodiment 1, it is simply determined whether a voltage detection line is disconnected or the cell voltage has decreased when the terminal voltage connected to the highest or the lowest voltage detection line decreases. In the case of the disconnection of the voltage detection line, since it is not the abnormality of the cell itself, a level of the trouble is slight. In the case of the pure EV, when power supply from power supply system 1 is stopped, the pure EV cannot drive by itself. In this situation, it is necessary that another car tows this pure EV or a wrecker moves this pure EV. Therefore, in this exemplary embodiment, in the case of the disconnection of the voltage detection line, the use of power supply system 1 corresponding to the predetermined time and/or the predetermined travel distance is allowed. Thereby, the safety and the convenience can be made compatible.

In the case of the disconnection of positive power supply line L0 or negative power supply line L10, the result of the cell voltage detection corresponding to the disconnected cell in cell voltage detection circuit 31 is made largely different, or the operation of cell voltage detection circuit 31 is stopped due to the stop of power supply. In addition to this, since the output of the detection of total voltage detection circuit 33 decreases largely, the determination of the disconnection can be made based on the outputs of the two circuits, similarly.

### Second Exemplary Embodiment

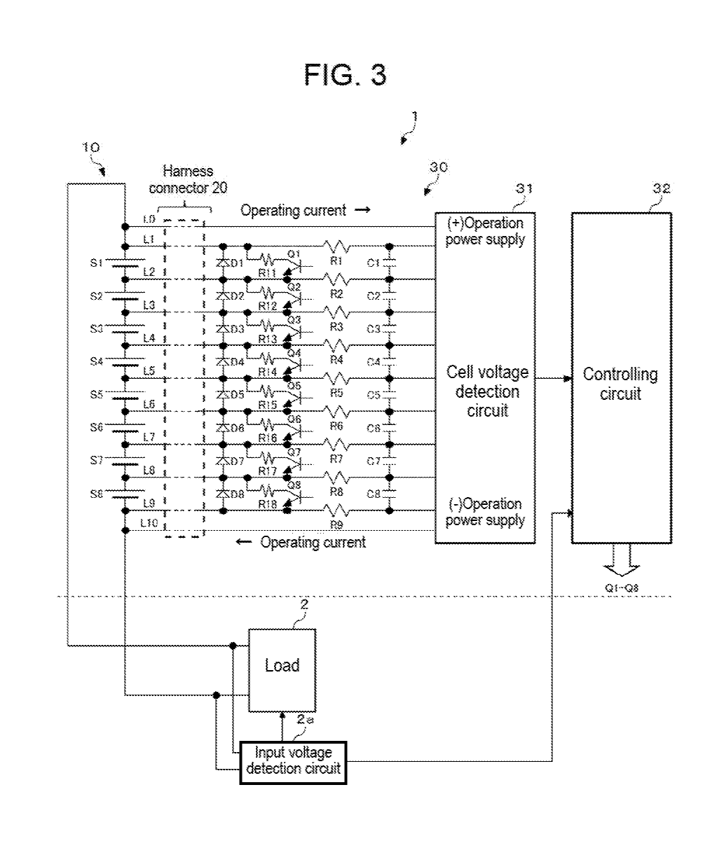

FIG. 3 is a diagram for describing power supply system 1 according to an exemplary embodiment 2 of the present invention. In power supply system 1 relating to the exemplary embodiment 2, total voltage detection circuit 33 is omitted, compared with power supply system 1 relating to the exemplary embodiment 1. In place of it, in the exemplary embodiment 2, controlling circuit 32 obtains an input voltage of load 2 from input voltage detection circuit 2a disposed at the load side. Controlling circuit 32 uses the obtained input voltage of load 2 in place of the total voltage relating to the exemplary embodiment 1.

Here, in a case where load 2 is an AC load and input voltage detection circuit 2a measures an inverter output, the inverter (not shown in figures) is provided between power supply system 1 and load 2. In this case, the detected voltage of input voltage detection circuit 2a is the AC voltage. Controlling circuit 32 converts an AC voltage value obtained from input voltage detection circuit 2a into a DC voltage value. it is preferable to convert the AC voltage value into the DC voltage value so as to compensate a wiring impedance between power storage module 10 and load 2.

Controlling circuit 32 of power supply system 1 and input voltage detection circuit 2a may be connected through communication line (for example, RS-485 or TCP/IP), or directly through voltage line. The voltage value detected by input voltage detection circuit 2a may be transmitted so as to superpose it on the voltage line between power storage module 10 and load 2.

As mentioned above, according to the exemplary embodiment 2, compared with the exemplary embodiment 1, total voltage detection circuit 33 can be omitted, while the configuration of management device 30 is simplified further, the similar effect to the exemplary embodiment 1 is produced. Here, it needs the following condition: input voltage detection circuit 2a being disposed at the load side; input voltage detection circuit 2a and controlling circuit 32 being connected; and power storage module 10 being not connected in series to another power storage module. On the other hand, the exemplary embodiment 1 is not limited by these conditions, and has the effect.

The present invention has been described based on the exemplary embodiment. A person of the ordinary skill in the art can understand that the exemplary embodiment is illustrative only, constitution elements and combined processes can be modified, and such modified examples are covered by the scope of the present invention.

For example, in the exemplary embodiment 2, positive power supply line L0 and voltage detection line L1 are combined as one line, and voltage detection line L1 may function as both of the power supply line and the voltage detection line. Similarly, voltage detection line L9 and negative power supply line L10 are combined as one line, and voltage detection line L9 may function as both of the power supply line and the voltage detection line.

In the above-mentioned exemplary embodiment, the example is assumed that power supply system 1 is used for a power source device for vehicles. However, the power storage system is not limited to use for vehicles, and then can be used as the power source device for airplanes, for ships, for stationary types, or for other uses.

The exemplary embodiment may be specified by items described below.

[Item 1]

A management device (30) including:

a cell voltage detection circuit (31) that is connected to each node of a plurality of cells (S1-S8) connected in series by voltage detection lines (L1-L9), and detects the voltage of each of the cells (S1-S8);

a total voltage detection circuit (33) that detects the voltage between the highest node and the lowest node of the cells (S1-S8); and

a controlling circuit (32) that compares the total voltage detected by the total voltage detection circuit (33) and a cell voltage sum obtained by adding the cell voltages of the cells (S1-S8) detected by the cell voltage detection circuit (31) when the cell voltage of the highest cell or the lowest cell detected by the cell voltage detection circuit (31) is abnormal, wherein in a case where the total voltage and the cell voltage sum match, the controlling circuit (32) determines that the highest cell (S1) or the lowest cell (S8) is abnormal, and in a case where the total voltage and the cell voltage sum do not match, the controlling circuit (32) determines that a disconnection of the highest voltage detection line (L1) or the lowest voltage detection line (L9) occurs.

According to this, it is simply determined whether the highest or lowest voltage detection line (L1/L9) is disconnected or the highest or lowest cell (S1/S8) becomes abnormal state.

[Item 2]

The management device (30) according to item 1,

wherein an operation power supply of the cell voltage detection circuit (31) is fed from both ends of the plurality of cells (S1-S8),

the highest node of the plurality of cells (S1-S8) and the cell voltage detection circuit (31) are connected by two lines of the voltage detection line (L1) and a positive power supply line (L0),

the lowest node of the plurality of cells (S1-S8) and the cell voltage detection circuit (31) are connected by two lines of the voltage detection line (L9) and a negative power supply line (L10), and

the total voltage detection circuit (33) detects the voltage between the positive power supply line (L0) and the negative power supply line (L10).

According to this, regardless of whether or not the voltage detection line is disconnected, the whole voltage of the plurality of cells (S1-S8) can be measured.

[Item 3]

A management device (30) including:

a cell voltage detection circuit (31) that is connected to each node of a plurality of cells (S1-S8) connected in series by voltage detection lines (L1-L9), and detects the voltage of each of the cells (S1-S8); and

a controlling circuit (32) that compares an input voltage of a load obtained by an input voltage detection circuit (2a) that is connected to input terminals of the load (2) connected to both ends of the cells (S1-S8) and a cell voltage sum obtained by adding the cell voltages of the cells (S1-S8) detected by the cell voltage detection circuit (31) when the cell voltage of the highest cell or the lowest cell detected by the cell voltage detection circuit (31) is abnormal, wherein in a case where the input voltage and the cell voltage sum match, the controlling circuit (32) determines that the highest cell (S1) or the lowest cell (S8) is abnormal, and in a case where the input voltage and the cell voltage sum do not match, the controlling circuit (32) determines that a disconnection of the highest voltage detection line (L1) or the lowest voltage detection line (L9) occurs.

According to this, it is simply determined whether the highest or lowest voltage detection line (L1/L9) is disconnected or the highest or lowest cell (S1/S8) becomes abnormal state.

[Item 4]

The management device according to any one of items 1 to 3,

wherein when the controlling circuit (32) determines that the disconnection of the highest voltage detection line (L1) or the lowest voltage detection line (19) occurs, the controlling circuit (32) allows a power supply from the cells (S1-S8) to the load by a predetermined time or a predetermined amount of electric power.

According to this, the safety and the convenience can be made compatible.

[Item 5]

A power supply system (1) including:

a power storage module (10) in which a plurality of cells (S1-S8) are connected in series; and

the management device (30) according to any one of items 1 to 4 that manages the power storage module (10).

According to this, it is simply determined whether the highest or lowest voltage detection line (L1/L9) is disconnected or the highest or lowest cell (S1/S8) becomes abnormal state.

### REFERENCE MARKS IN THE DRAWINGS

1 power supply system
2 load
2a input voltage detection circuit
10 power storage module
S1-S8 cell
L0 positive power supply line
L1-L9 voltage detection line
L10 negative power supply line
20 harness connector
30 management device
R1-R9 resistor
C1-C8 capacitor
R11-R18 discharge resistor
Q1-Q8 discharge switch
D1-D8 diode
31 cell voltage detection circuit
32 controlling circuit
33 total voltage detection circuit

1. A management device comprising:
a cell voltage detection circuit that is connected to each node of a plurality of cells connected in series by voltage detection lines, and detects the voltage of each of the cells;
a total voltage detection circuit that detects the voltage between the highest node and the lowest node of the cells; and
a controlling circuit that compares the total voltage detected by the total voltage detection circuit and a cell voltage sum obtained by adding the cell voltages of the cells detected by the cell voltage detection circuit when the cell voltage of the highest cell or the lowest cell detected by the cell voltage detection circuit is abnormal,
wherein in a case where the total voltage and the cell voltage sum match, the controlling circuit determines that the highest cell or the lowest cell is abnormal, and
in a case where the total voltage and the cell voltage sum do not match, the controlling circuit determines that a disconnection of the highest voltage detection line or the lowest voltage detection line occurs.

2. The management device according to claim 1,
wherein an operation power supply of the cell voltage detection circuit is fed from both ends of the plurality of cells,
the highest node of the plurality of cells and the cell voltage detection circuit are connected by two lines of the voltage detection line and a positive power supply line,
the lowest node of the plurality of cells and the cell voltage detection circuit are connected by two lines of the voltage detection line and a negative power supply line, and
the total voltage detection circuit detects the voltage between the positive power supply line and the negative power supply line.

3. A management device comprising:
a cell voltage detection circuit that is connected to each node of a plurality of cells connected in series by voltage detection lines, and detects the voltage of each of the cells;
a controlling circuit that compares an input voltage of a load obtained by an input voltage detection circuit that is connected to input terminals of the load connected to both ends of the cells and a cell voltage sum obtained by adding the cell voltages of the cells detected by the cell voltage detection circuit when the cell voltage of the uppermost cell or the lowermost cell detected by the cell voltage detection circuit is abnormal,
wherein in a case where the input voltage and the cell voltage sum match, the controlling circuit determines that the uppermost cell or the lowermost cell is abnormal, and
in a case where the input voltage and the cell voltage sum do not match, the controlling circuit determines that a disconnection of the highest voltage detection line or the lowest voltage detection line occurs.

4. The management device according to claim 1,
wherein when the controlling circuit determines that the disconnection of the highest voltage detection line or the lowest voltage detection line occurs, the controlling circuit allows a power supply from the cells to the load by a predetermined time or a predetermined amount of electric power.

5. A power supply system comprising:
a power storage module in which a plurality of cells are connected in series; and
the management device according to claim 1, that manages the power storage module.

6. The management device according to claim 2,
wherein when the controlling circuit determines that the disconnection of the highest voltage detection line or the lowest voltage detection line occurs, the controlling circuit allows a power supply from the cells to the load by a predetermined time or a predetermined amount of electric power.

7. The management device according to claim 3,
wherein when the controlling circuit determines that the disconnection of the highest voltage detection line or the lowest voltage detection line occurs, the controlling circuit allows a power supply from the cells to the load by a predetermined time or a predetermined amount of electric power.

8. A power supply system comprising:
a power storage module in which a plurality of cells are connected in series; and
the management device according to claim 2, that manages the power storage module.

9. A power supply system comprising:
a power storage module in which a plurality of cells are connected in series; and
the management device according to claim 3, that manages the power storage module.

10. A power supply system comprising:
a power storage module in which a plurality of cells are connected in series; and
the management device according to claim 4, that manages the power storage module.
